(19) United States
(12) Patent Application Publication
(10) Pub. No.: US 2017/0176740 A1
(43) Pub. Date: Jun. 22, 2017

(54) METHOD OF FABRICATING A MICROELECTRONIC DEVICE WITH BURIED DARK LAYERS

(71) Applicant: Texas Instruments Incorporated, Dallas, TX (US)

(72) Inventors: Lance William Barron, Plano, TX (US); Jose Antonio Martinez, Murphy, TX (US); Earl Vedere Atnip, Plano, TX (US)

(21) Appl. No.: 15/003,082

(22) Filed: Jan. 21, 2016

Related U.S. Application Data
(60) Provisional application No. 62/268,601, filed on Dec. 17, 2015.

(51) Int. Cl. G02B 26/08; C23C 16/30; G02B 1/111; C23C 16/50

(52) U.S. Cl. CPC G02B 26/0833; C23C 16/50; C23C 16/30; G02B 1/111

(57) ABSTRACT

A microelectromechanical system (MEMS) is comprised of a micromirror attached to a semiconductor device. A stack of inorganic high index materials comprised of titanium oxide, titanium nitride, and titanium is deposited above metal levels within the semiconductor device. Another stack of inorganic high index materials comprised of titanium oxide, titanium nitride, and titanium may be deposited in a continuous or dis-continuous layer within one or more of the dielectric layers. Each stack of high index material films is deposited at a depth and of thickness to achieve a minimum reflectance for the entire film system and to ensure maximum destructive interference at the targeted wavelength range. The high index material stack results in reduced light scattering during operation of the micromirror and improves contrast of the display system.

### CROSS-REFERENCE TO RELATED APPLICATION

This application claims priority to U.S. Provisional Patent Application Ser. No. 62/268,601, filed Dec. 17, 2015, which is hereby fully incorporated herein by reference for all purposes.

### FIELD OF THE INVENTION

This relates generally to the fabrication of microelectromechnical systems (MEMS) and, in particular, to fabrication of the digital micromirror device (DMD).

### BACKGROUND

The micromirror is a spatial light modulator within a display system that uses digital image data to modulate a beam of light by selectively reflecting portions of the light beam onto a display screen.

A digital micromirror device (DMD), such as a Texas Instruments DLP® micromirror device, uses an array of individually positionable micromirrors to form an image onto a display panel. An image is formed by positioning micromirrors in “ON” and “OFF” positions using a pulse-width modulation scheme. This scheme is determined by bit planes generated by data for each image frame based on data received for each pixel. When the system is operating, the lamp is illuminated. In the “ON” position, the micromirror directs incident light onto a display target through a projection lens. FIG. 1 shows a micromirror 102 in an “OFF” position. Light from a lamp 104 incident on the micromirror 102 is directed away from the projection lens 106 and onto a light absorber 108.

One parameter measured in projection system performance is contrast. Contrast is degraded due to unwanted light reflecting from the underlying complementary metal-on-silicon (CMOS) circuitry which reaches the screen. Low contrast limits the system's capability to produce rich colors.

FIG. 2 shows a top view of a CMOS structure 202. FIG. 3 shows the same figure with the micromirror 304 formed above the CMOS structure 202. The micromirror 304 covers a majority of the CMOS 202 surface but some small portion of it is not covered by the micromirror 304. Ideally, when the micromirrors are in the OFF state (black screen), no light should reach the screen. In reality, some light is reflected from the CMOS metallization layers, degrading contrast.

Contrast is negatively impacted by light scattered from underlying structures below the micromirror. A thin metal layer below the micromirror forms a hinge which supports the thicker metal layer of the micromirror forming a rigid member with a mirror-like surface. The rigid member remains flat while the hinge deforms, an action which minimizes the amount of light scattered by the device and improves the device's contrast ratio.

CMOS circuitry embedded within the substrate and attached to the overall micromirror structure applies electrical signals which transmit instructions to the micromirror. Both incident light and scattered light can strike the semiconductor device during operation and be reflected. Although an antireflective coating may be applied to the underlying support structure of the micromirror, light may scatter from underlying metal levels within the semiconductor device. Light may scatter from the first metal level through the top metal level. Semiconductor devices typically comprise one or more metal levels and semiconductor devices used with micromirrors typically comprise at least three metal levels.

Experimental data taken during fabrication of the semiconductor device shows that a metal layer may reflect between 2% and 24% of light, depending on the depth of the metal layer and the wavelength of the light. Amount of reflection from metal levels within the semiconductor device may also vary depending on metal films used, metal film thicknesses, interlevel oxide film, and thickness of oxide film.

FIG. 4 illustrates a micromirror-based projection system 400. Light from a light source 402 is focused on the entrance pupil of an integrating rod 404 using a lens group 406. A reflective aperture stop 408 is set at the entrance pupil of the integrating rod 404. Light striking the reflective aperture stop 408 is reflected back to the light source 402 and only light entering the entrance pupil passes through the integrating rod 404. The integrating rod 404 homogenizes the light which passes through it. Light exiting the integrating rod 404 passes through a color wheel 410, which may be a scrolling color wheel or other type of color wheel.

The light passing through the color wheel 410 is then focused by the group of lenses 412. An aperture stop 414 is typically located in the group of lenses 412. The group of lenses 412 focuses the exiting light onto a spatial light modulator 416 through a TIR prism assembly 418. The TIR prism assembly 418 is a commercially available combination of two prisms, for example by Young Optics Inc., used in directing light in optical display systems. The spatial light modulator 416 comprises antireflective coatings and insulating layers. The OFF-state light and the flat state light may be directed to a light dump 420 which redirects the light away from the display panel.

The ON-state light exits the TIR prism assembly 418 and enters the group of projection lenses 422. Another aperture stop 424 is typically used with the group of projection lenses 422 to block an unwanted portion of the light, preventing it from passing through the lenses 422 to the image plane 426. The controller 428 sends image data and control signals to the spatial light modulator 416 to modulate the light in order to form an image on the image plane 426.

FIG. 5 (PRIOR ART) is a view of a micromirror 500. Multiple subcomponents of the micromirror can scatter light and reduce contrast. Light reflection primarily occurs from the deformable micromirror 502 yet scattering may occur from the torsion beam formed by the hinge 504, torsion beam supports 506, mirror via support 508, as well as the hinge via supports 510 and other subcomponents.

An antireflective coating (ARC) layer of one or more layers of a high index material work together to reduce reflection through interference of light. ARC layers may be used during photolithography sequences in semiconductor fabrication to improve resolution of lithography features. ARC layers are also used on structures such as the micromirror assembly to minimize extraneous light and prevent further light scattering.

During photolithography processing, the ARC layer is deposited across the semiconductor wafer. The ARC layer serves to reduce internal light scatter between layers and to reduce light scatter from lithography sources. The results are typically improved line width resolution of lithography features and the ability to resolve smaller sized features.

ARC layers are specifically formulated to support specific optical parameters. These parameters comprise a refractive index n, an extinction coefficient k, and a thickness d, all of which are designed to ensure that the reflected light that passes through the ARC-substrate interface is equal in amplitude and opposite in phase to the reflected light from the photoresist-ARC interface. In this manner, the reflected light is cancelled by destructive interference and the photoresist receives a minimum reflected wave from the substrate.

FIG. 6A is an illustration depicting a substrate 602 without an ARC layer. There is a photoresist film 608 deposited above the top substrate 602 surface. The photoresist 608 is patterned and etched to form features 610. When energy 612, in the form of photons, is incident upon the top surface of the substrate 602, through photoresist 608, a large portion of the energy 612 exposes the photoresist 608. A small portion of the energy 612 is reflected at the photoresist-substrate interface 614 and is back-scattered through the photoresist 608. These portions of photoresist 608 are further exposed from below their surface by the reflected light and feature lines and edges are roughened and further enlarged.

In FIG. 6B, an ARC layer 606 has been deposited between the substrate 604 and the photoresist 608. The energy 612 is incident upon the photoresist 608. The ARC layer 606 generates destructive interference at the photoresist-ARC layer interface 618 and reflected light is dissipated within the ARC layer 606. Reflected light is of the same magnitude and intensity as the initial scattered light but of the opposite phase. The opposite phase cancels the reflected light from the substrate-ARC interface 616. The light reflected onto the bottom of the photoresist layer 608 is minimized. Features 620 are prevented from further exposure from back-scattered light 612.

Photoresist is an organic, photo-sensitive compound which changes its chemical structure after exposure to light of a certain wavelength. It is typically formulated to be used at a specific lithography wavelength such as at i-line (365 nm) or at deep ultra violet (DUV) (248 nm) or at 193 nm. Formulations are proprietary to manufacturers such as AZ Electronic Materials, JSR Micro Inc., and Sumitomo Chemical Inc. among others. Photoresist can be positive, where exposed photoresist becomes soluble in a developer solution or negative, where unexposed photoresist is soluble in a developer solution. During photolithography, either organic or inorganic ARC is used to minimize light scattering within the photoresist. Organic ARC is deposited using spin coating, a deposition method similar to that of deposition of photoresist. Inorganic ARC is deposited using a method such as plasma enhanced chemical vapor deposition (PECVD).

Antireflective coatings (ARC) are typically used in combination with photoresist to improve patterning. ARC layers used during photolithography are typically removed from the semiconductor surface prior to the next fabrication step in the sequence.

ARC materials comprise organic materials such as polymer based liquid chemistries, from Brewer Science, Inc. Typical deposition methods are similar to photoresist deposition methods and include spin coating to spread a liquid across the surface of the semiconductor wafer for coverage. ARC layers are manufactured using proprietary chemistries to absorb only specific wavelengths, for example deep ultra violet (DUV) or 248 nm light. Organic ARCs are not photosensitive and are deposited in film thicknesses thinner than typical photoresist layers.

Organic ARC films can comprise a top antireflective coating (TARC) or a bottom antireflective coating (BARC). TARC films are applied above the photoresist layer and TARC films are applied between the substrate and the photoresist layer. TARC absorbs light to reduce reflection at the substrate-photoresist interface. BARC absorbs light and uses destructive interference to reduce reflection at the photoresist-ARC interface. In the example embodiment, an organic BARC is used during photolithography processing. It absorbs approximately 3% of light at 248 nm.

ARC layers can also comprise inorganic materials such as dielectric films which are typically deposited using plasma enhanced chemical vapor deposition (PECVD). One inorganic ARC film is a silicon oxynitride (SiₓO_{y}N_{z}). Other inorganic ARC films are a titanium nitride (TiN) or a titanium oxide (TiO₂).

An approach for reducing light scattering in a digital micromirror is to cover underlying micromirror structures with an antireflective film to reduce light scattering. The antireflective film absorbs light when film thickness is adequate and coverage is complete.

Another approach to reducing light scattering is to place a larger portion of the underlying support structure within the area of the top reflective portion of the micromirror surface. The rigid micromirror surface forms a protective and reflective umbrella above the underlying structures as seen in FIG. 3.

### SUMMARY

An integrated ARC film stack for the underlying MEMS CMOS structure is proposed which comprises one or more metal levels separated by dielectric layers. Films of high index materials are stacked above metallization layers in the CMOS device. One or more stacks of layers of high index of refraction material such as TiO₂ are added at a specific thickness and position in a way that the layer or layers interacts with the already present dielectric materials, forming anti-reflective stacks. These stacks significantly reduce light reflected from the CMOS device minimizing unwanted light reaching the screen. This effect allows projection systems to have higher contrast, therefore producing rich colors.

Each metal level is separated from the next metal level by a dielectric layer. A via is patterned into each dielectric layer and connects the first metal stack to the second metal stack and the second metal stack to the third metal stack. The dielectric layer is composed of a deposited dielectric such as tetraethyl orthosilicate (TEOS) (Si(OC₂H5)₄) or other plasma enhanced chemical vapor deposited (PECVD) oxide. Metal levels other than the top metal M3 level are comprised of a metal such as aluminum copper (AlCu) with an ARC stack layer above. The example embodiment comprises three metal levels although it is possible that a semiconductor device may comprise more or less than three metal levels.

A first dielectric layer is deposited above the CMOS circuitry and on the substrate. A first metal level is patterned into the first dielectric layer and metal is deposited into this opening. A first layer of a stack of high index materials is deposited above the first metal level. A second dielectric layer is deposited above the first stack of high index layers. A via opening is patterned into the second dielectric layer and metal deposited within the opening to form a first via. A second metal level is patterned into the second dielectric layer and metal deposited into the opening. A second stack of high index material layers is deposited above the second metal level. A third dielectric layer is deposited above the second stack of high index materials layers. A second via opening is patterned into the third dielectric layer and metal is deposited within the opening to form a second via. A third metal level is patterned into the third dielectric layer and metal is deposited into the opening. A third stack of high index material layers is deposited above the third second metal level. A top dielectric layer is deposited above the third stack of high index material layers. One or more continuous or discontinuous stack of high index material layers may also be embedded within one or more of the dielectric layers.

A stack of inorganic high index material layers is deposited on each metal level. It is an advantage to use inorganic materials which can be tuned to a targeted wavelength of light in optical display systems. Film thickness, depth and position of each stack of high index material layers are adjusted to address the goal of minimum reflectance for entire film stack and maximum destructive interference for the targeted wavelength range in the optical display system.

### BRIEF DESCRIPTION OF THE DRAWINGS

Example embodiments are described with reference to accompanying drawings, wherein:

FIG. 1 (Prior Art) is a view of the “OFF” state of a micromirror.

FIG. 2 (Prior Art) is a top view of a CMOS circuit.

FIG. 3 (Prior Art) is a top view of the CMOS circuit with a micromirror.

FIG. 4 (Prior Art) is a drawing of a micromirror based projection system.

FIG. 5 (Prior Art) illustrates portions of a micromirror element from an array.

FIGS. 6A-B provide illustrations of light interference.

FIG. 7 illustrates a device with three levels of metal, each with a stack of high index material layers.

FIG. 8 is an exploded view of a stack of high index material layers from FIG. 7.

FIG. 9 illustrates a device with three levels of metal, each with a stack of high index material layers and with a buried stack of high index material layers.

FIG. 10 is a flow chart showing a sequence of steps in the example method.

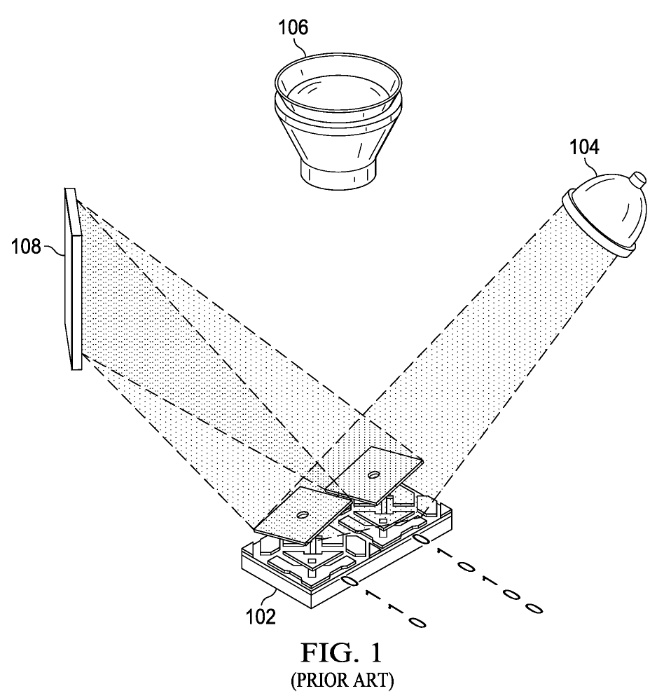

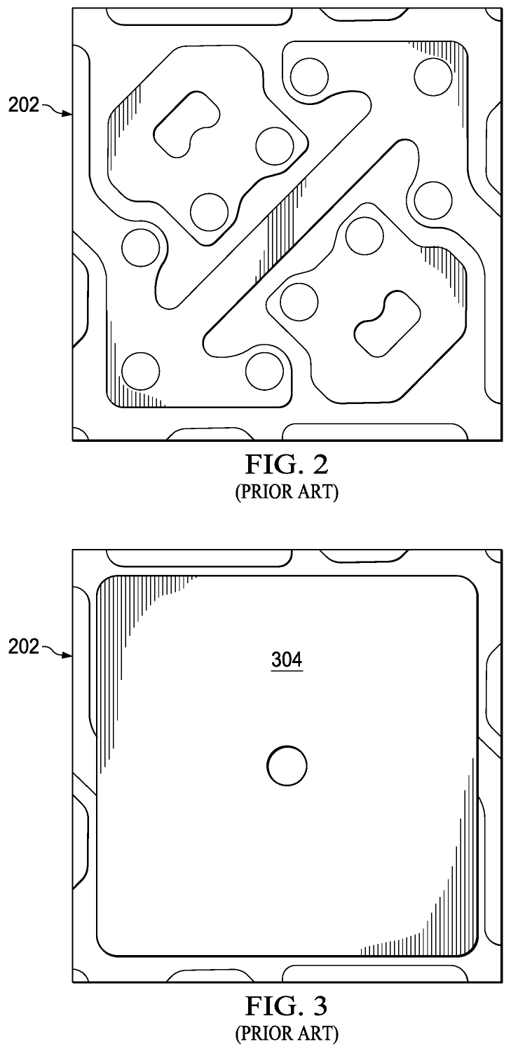

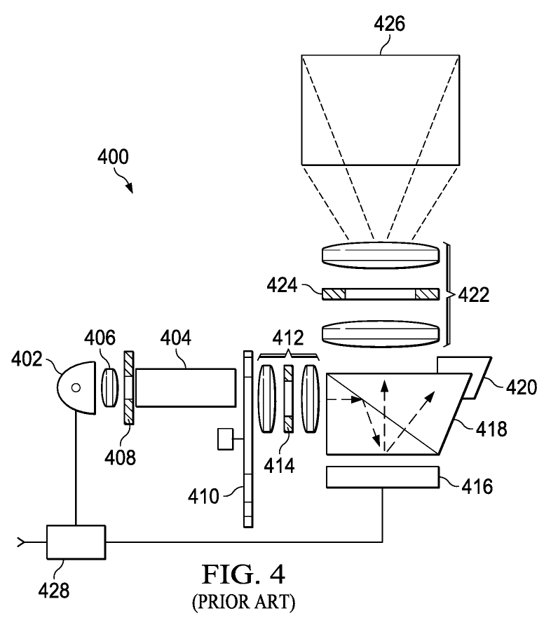

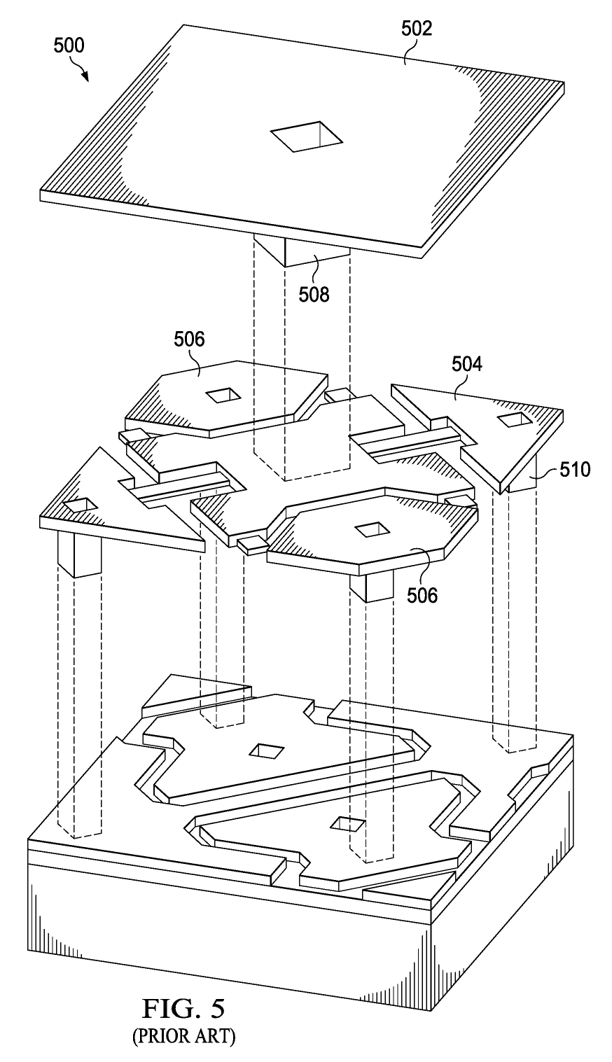

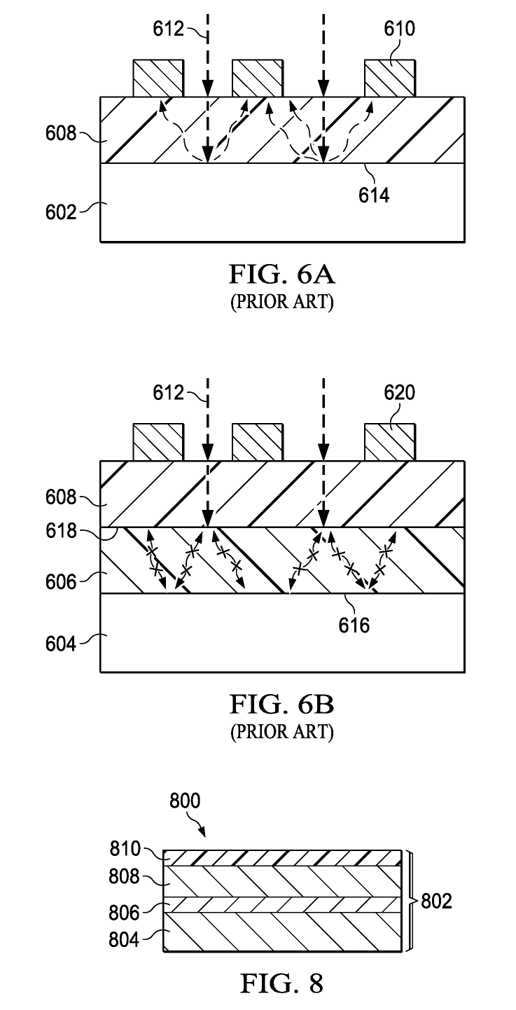

### DETAILED DESCRIPTION OF EXAMPLE EMBODIMENTS

The steps described below are typically undertaken on a wafer level scale, with multiple instances of the illustrated structures simultaneously formed to define arrays of such structures formed at respective die areas of corresponding simultaneously formed DMD's.

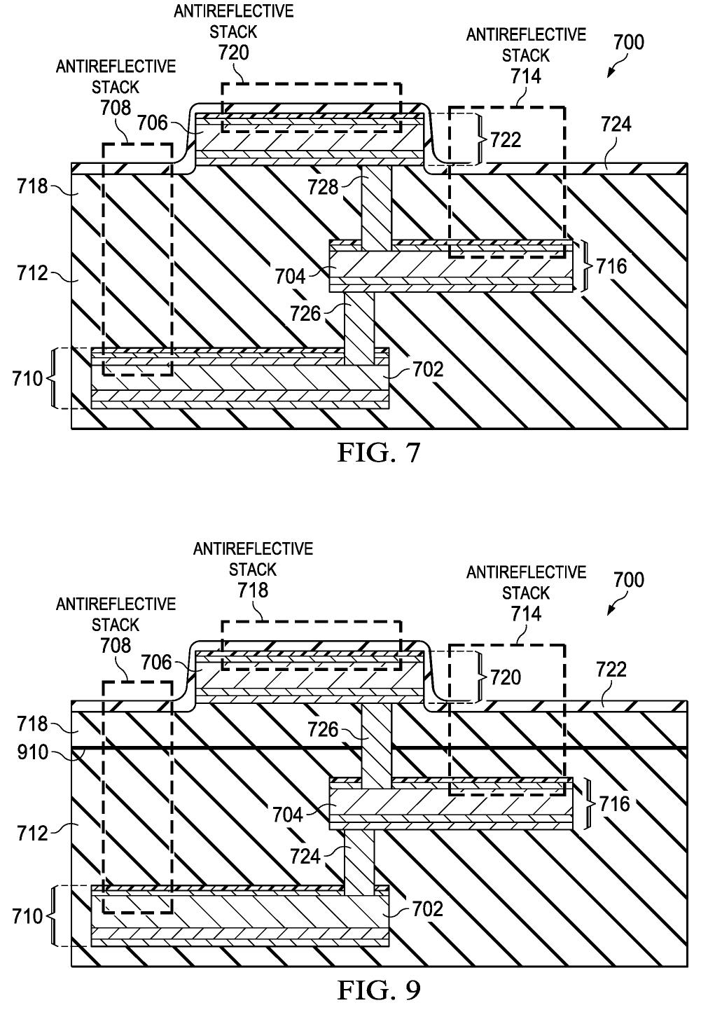

FIG. 7 illustrates a multi-level metal structure, typically configured as part of a semiconductor device. The structure shown is one possible implementation consisting of depositing a stack of high index material layers on top of each metallization layer. This implementation is targeted towards antireflective properties for light at visible wavelengths.

FIG. 7 comprises CMOS circuitry 700. Three metal levels, designated as metal 1 (M1) 702, metal 2 (M2) 704, and metal 3 (M3) 706 are vertically spaced, connected by via levels and separated by dielectric layers. The bottom metal level is M1 702. The second metal level above M1 702 is M2 704 and the top metal level is M3 706. It is possible for the CMOS circuitry 700 to be comprised of more than three metal levels. Dielectric thicknesses for M2 704 and M3 706 are included in the calculations for maximum antireflection.

The first antireflective stack 708 is comprised of M1 702 with stack 710 and dielectric layer 712. The second antireflective stack 714 is comprised of M2 704 with stack 716 and dielectric layer 718. The top and third antireflective stack 720 is comprised of M3 706, stack 722 and dielectric layer 724. Therefore, the top M3 706 antireflective stack 722 is optimized differently from M1 702 stack 710 and M2 704 stack 716.

In an example embodiment, M1 702 is comprised of a stack 710 of approximately 200 A of Ti above 700 A of TiN, above 210 A of TiO₂. The thickness of dielectric layer 712 deposited above the stack 710 is approximately 20,000 A and is not a required component of antireflective properties for stack 708. M2 704 is comprised of a stack 716 of approximately 125 A of TiO₂ above 900 A of TiN, above 2500 A of an alloy of approximately 98.8% Al, 0.2% Ti, and 1.0% Si, which is primarily Al. The 2500 A of aluminum alloy are deposited above 425 A of TiN, above 200 A of Ti. The thickness of dielectric layer 718 is targeted to approximately 6300 A for optimal antireflective properties for the antireflective stack 714. M3 706 comprises a stack 722 of approximately 900 A of TiN above 125 A of TiO₂ with a dielectric layer 724 thickness of approximately 650 A to form the antireflective stack 718.

The first metal level, M1 702, is attached to M2 704 by a via 726. The second metal level, M2 704, is attached to M3 706 by a via 728. Metal levels and vias are surrounded by dielectric layers. Dielectric layer 712 is deposited above M1 702. Dielectric layer 718 is deposited above M2 704 and dielectric layer 724 is deposited above M3 706. The dielectric layers are comprised of a deposited dielectric such as TEOS.

FIG. 8 is an exploded view of an example metal level stack 800. Each metal level stack 802 is deposited above a base layer 804 of a metal such as aluminum copper or AlCu. A first layer 806 of Ti is deposited above the AlCu. A second layer 808 of TiN is deposited above the first layer 806. A third and top layer 810 of TiO₂ is deposited above the second layer 808. TiO2 is a typical inorganic ARC film. Layer 806 of Ti is not required for M3 706.

In an example embodiment, depositing a stack of high index material layers at the defined thickness, along with adjustments to the thickness of the dielectric materials already present, allows achievement of efficient antireflective stacks.

Deposition parameters may be adjusted for each level resulting in an optimal optical index of refraction, n, and the extinction or loss coefficient, k. The targeted n value for the stack 800 is between 2.5 and 2.7.

The index of refraction, n, is the factor by which the velocity and wavelength of radiation is changed through a material relative to the velocity and wavelength of the same radiation in a vacuum. Refractive index of a material varies with the wavelength of the radiation.

The extinction or loss coefficient, k, is the rate of decay of the radiation through the material. It is also wavelength dependent.

The efficiency of the antireflective stacks can be increased further by creating higher order antireflective stacks. One method is by burying an additional stack of high index materials within the dielectric layers between M2 704 and M3 706. FIG. 9 describes this method. Another option is to place the stack of high index material layers between M1 702 and M2 704.

In FIG. 9, a buried stack 910 of high index material layers is added to CMOS circuitry 700. This stack 910 is deposited between M2 704 and M3 706 in the example embodiment. It is possible to bury the stack 910 between M1 702 and M2 704 or to bury one or more stacks in multiple locations within the CMOS structure. It is also possible to bury the stack 910 in a discontinuous manner in the horizontal plane.

Stack 910 is comprised of Ti—TiN—TiO₂ as described in FIG. 8. Layer thicknesses, stoichiometry, and depth within the CMOS structure 700 are customized to obtain targeted optical interference for the entire film system.

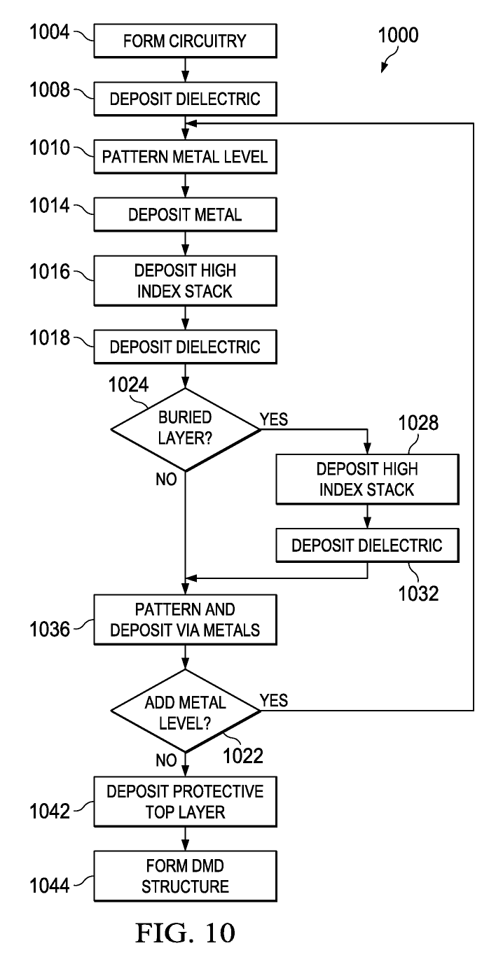

FIG. 10 is a flow diagram of the sequence of operations 1000 for the deposition of high index materials on metal layers and buried or embedded antireflective layers within the dielectric layers of a semiconductor device. The sequence of operations 1000 results in a superstructure.

CMOS circuits are formed within a semiconductor substrate in block 1004. A dielectric is deposited above the CMOS circuit in block 1008. The dielectric is patterned in block 1010 so that a metal such as AlCu may be deposited above the patterned area in block 1014. In block 1016, a stack of high index materials such as Ti—TiN—TiO_{X} is deposited above the metal and within the patterned portion. In block 1018, a dielectric is deposited above a high index of materials stack. If a buried stack is to be deposited in block 1024, a stack of Ti—TiN—TiOₓ is deposited in block 1028 followed by deposition of a dielectric above stack in block 1032. A via is patterned within the dielectric and metal deposited in block 1036. A decision is made in block 1038 to deposit another metal level. If no further metal levels are deposited, a protective top layer is deposited in block 1042 and a DMD structure is formed above the CMOS superstructure in block 1044.

If a buried stack of high index material layers is not required, another decision is made whether to manufacture an additional metal level in block 1020. If the decision is made to include another metal level in block 1020, the process sequence is repeated from block 1006. If no further metal levels are to be formed in block 1020, a top dielectric layer is deposited in block 1022. Once the top dielectric is deposited, the DMD structure is fabricated above the completed semiconductor device.

The described methodology may offer many advantages.

Addressing reflection of light from metal levels below the optical display system may aid with improvements in photolithography during fabrication of the CMOS semiconductor system. The use of high index materials on metal levels in the device may address the possibility of unintentional exposure of photoresist to scattered light, allowing improved feature edges and line width resolution, and driving reductions in feature size.

Adding a stack of high index material layers above the metal levels in the semiconductor device may also improve the capability of the optical display system for process tolerance. For example, it is possible that reduced light reflection from metal levels may allow patterning of smaller features, sharper edges, and narrower line widths of the optical display system technology.

Burying stacks of high index material layers within the CMOS structure minimizes interference with contrast of the MEMS device.

Most importantly, addressing light scattered from metal levels within the semiconductor device, may reduce light scattered during operation of an optical display system, thereby increasing contrast and improving quality.

Including buried stacks of high index material layers between metal levels may further reduce reflected light. The use of continuous or discontinuous between one or more metal levels addresses the issue of reflected light between metal-high index material layers.

Those skilled in the art to which the invention relates will appreciate that modifications may be made to the described example embodiments, and also that many other embodiments are possible, within the scope of the claimed invention.

What is claimed is:

1. A method of fabricating a microelectronic device with buried stacks of high index material layers, comprising:
forming a first dielectric layer over a substrate;
depositing a first metal layer within the first dielectric layer;
depositing a first stack of high index material layers on the first metal layer;
depositing a second dielectric layer above the first stack of high index material layers;
depositing a second metal layer within the second dielectric layer;
depositing a second stack of high index material layers on the second metal layer;
depositing a third dielectric layer above the second stack of high index material layers;
depositing a third metal layer within the third dielectric layer;
depositing a third stack of high index material layers on the third metal layer;
depositing a fourth dielectric layer above the third stack of high index material layers; and
forming a microelectromechanical system (MEMS) element over the fourth dielectric layer.

2. The method of claim 1, the stack of high index material layers further comprises an index of refraction greater than or equal to 2.5 and smaller than or equal to 2.7.

3. The method of claim 2, the stack of high index material layers comprises inorganic films.

4. The method of claim 3, wherein the stack of high index material layers comprises a titanium oxide layer, a titanium nitride layer, and a titanium layer.

5. The method of claim 1, wherein the first, second, third, and fourth dielectric layers each comprises tetraethyl orthosilicate (TEOS).

6. The method of claim 1, wherein the first, second, third, and fourth dielectric layers each comprise plasma enhanced chemical vapor deposited oxide.

7. The method of claim 1, further comprising a fourth stack of high index material layers embedded within dielectric material between metal levels such that the dielectric material separates the fourth stack of high index material layers from the metal levels.

8. The method of claim 7, wherein the fourth stack of high index material layers is comprised of one or more discontinuous films.

9. A method of making a digital micromirror device, comprising:
providing a substrate with circuits;
depositing a first dielectric layer above the substrate;
patterning the first dielectric layer;
depositing a first metal layer within the patterned first dielectric layer;
depositing a first stack of high index material layers on the first metal layer;
depositing a second dielectric layer above the first stack of high index material layers;
patterning a first via opening within the second dielectric layer;
depositing a second metal layer within the opening of the second dielectric layer to form a first via;
depositing a third dielectric layer above the first stack of high index material layers and above the first via;
patterning the third dielectric layer;
depositing a third metal layer within the patterned third dielectric layer;
depositing a second stack of high index material layers on the third metal layer;
depositing a fourth dielectric layer above the first stack of high index material layers;
patterning a second via opening within the fourth dielectric layer;
depositing a fourth metal layer within the patterned opening to form a second via;
depositing a fifth dielectric layer above the second stack of high index material layers and above the second via;
patterning the fifth dielectric layer;
depositing a fifth metal layer within the patterned fifth dielectric layer;
depositing a third stack of high index material layers on the fifth metal layer; and
depositing a sixth dielectric layer above the third stack of high index material layers.

10. The method of claim 9, the stack of high index material layers further comprises an index of refraction greater than or equal to 2.5 and smaller than or equal to 2.7.

11. The method of claim 10, the stack of high index material layers comprises inorganic films.

12. The method of claim 11, wherein the stack of high index material layers comprises a titanium oxide layer, a titanium nitride layer, and a titanium layer.

13. The method of claim 9, further comprising one or more continuous stacks of high index material layers embedded within a dielectric material between and separated from metal levels.

14. The method of claim 9, wherein a buried stack of high index material layers is comprised of one or more discontinuous films.
